(19) United States
(12) Patent Application Publication
(10) Pub. No.: US 2016/0307963 A1
(43) Pub. Date: Oct. 20, 2016

(54) Array Of Memory Cells, Methods Associated With Forming Memory Cells That Comprise Programmable Material, And Methods Associated With Forming Memory Cells That Comprise Selector Device Material

(71) Applicant: Micron Technology, Inc., Boise, ID (US)

(72) Inventors: Max F. Hineman, Boise, ID (US); Jong Won Lee, Boise, ID (US)

(21) Appl. No.: 14/690,803

(22) Filed: Apr. 20, 2015

(51) Int. Cl. H01L 27/24; H01L 45/00

(52) U.S. Cl. CPC H01L 27/2427; H01L 27/2463; H01L 45/065; H01L 45/1233; H01L 45/141; H01L 45/1608

(57) ABSTRACT

In one embodiment, a method associated with forming a memory cell that comprises programmable material comprises forming a stack comprising sacrificial material over lower conductive material. The sacrificial material is first patterned in a first direction to form a sacrificial line. After the first patterning, second patterning is conducted of the sacrificial material of the sacrificial line in a second direction that crosses the first direction to form a sacrificial elevationally-extending projection from the sacrificial line. The sacrificial projection is replaced with phase change material to form an elevationally-extending projection comprising the phase change material. The phase change material projection is incorporated into one of the programmable material or a selector device component of the memory cell being formed. Other embodiments are disclosed.

### TECHNICAL FIELD

Embodiments disclosed herein pertain to arrays of memory cells, to methods associated with forming memory cells that comprise programmable material, and to methods associated with forming memory cells that comprise selector device material.

### BACKGROUND

Devices incorporating chalcogenide materials, e.g., ovonic threshold switches and phase change storage elements, may be found in a wide range of electronic devices. Such devices may be used in computers, digital cameras, cellular telephones, personal digital assistants, etc. Factors that a system designer may consider in determining whether and how to incorporate chalcogenide materials for a particular application may include, physical size, storage density, scalability, operating voltages and currents, read/write speed, read/write throughput, transmission rate, power consumption, and/or methods of forming devices with the chalcogenide materials, for example.

### BRIEF DESCRIPTION OF THE DRAWINGS

FIG. 1 is a diagrammatic top plan view of a substrate fragment in process in accordance with an embodiment of the invention.

FIG. 2 is a diagrammatic sectional view taken through line 2-2 in FIG. 1.

FIG. 3 is a view of the FIG. 1 substrate fragment at a processing step subsequent to that shown by FIG. 1.

FIG. 4 is a diagrammatic sectional view taken through line 4-4 in FIG. 3.

FIG. 5 is a view of the FIG. 3 substrate fragment at a processing step subsequent to that shown by FIG. 3.

FIG. 6 is a diagrammatic sectional view taken through line 6-6 in FIG. 5.

FIG. 7 is a view of the FIG. 5 substrate fragment at a processing step subsequent to that shown by FIG. 5.

FIG. 8 is a diagrammatic sectional view taken through line 8-8 in FIG. 7.

FIG. 9 is a diagrammatic sectional view taken through line 9-9 in FIG. 7.

FIG. 10 is a diagrammatic sectional view taken through line 10-10 in FIG. 7.

FIG. 11 is a view of the FIG. 7 substrate fragment at a processing step subsequent to that shown by FIG. 7.

FIG. 12 is a diagrammatic sectional view taken through line 12-12 in FIG. 11.

FIG. 13 is a diagrammatic sectional view taken through line 13-13 in FIG. 11.

FIG. 14 is a diagrammatic sectional view taken through line 14-14 in FIG. 11.

FIG. 15 is a view of the FIG. 11 substrate fragment at a processing step subsequent to that shown by FIG. 11.

FIG. 16 is a diagrammatic sectional view taken through line 16-16 in FIG. 15.

FIG. 17 is a diagrammatic sectional view taken through line 17-17 in FIG. 15.

FIG. 18 is a diagrammatic sectional view taken through line 18-18 in FIG. 15.

FIG. 19 is a view of the FIG. 15 substrate fragment at a processing step subsequent to that shown by FIG. 15.

FIG. 20 is a diagrammatic sectional view taken through line 20-20 in FIG. 19.

FIG. 21 is a diagrammatic sectional view taken through line 21-21 in FIG. 19.

FIG. 22 is a diagrammatic sectional view taken through line 22-22 in FIG. 19.

FIG. 23 is a view of the FIG. 19 substrate fragment at a processing step subsequent to that shown by FIG. 19.

FIG. 24 is a diagrammatic sectional view taken through line 24-24 in FIG. 23.

FIG. 25 is a diagrammatic sectional view taken through line 25-25 in FIG. 23.

FIG. 26 is a diagrammatic sectional view taken through line 26-26 in FIG. 23.

### DETAILED DESCRIPTION OF EXAMPLE EMBODIMENTS

Embodiments of the invention include methods associated with forming a memory cell that comprises programmable material, and an array of memory cells independent of method of manufacture. Any suitable existing or yet-to-be developed programmable materials may-be used. Ideally, the programmable material renders the fabricated memory cell to be non-volatile, although not necessarily so. Example programmable materials include phase change materials (e.g., chalcogenide materials). In some embodiments, the memory cell comprises a selector device (synonymous with “select device”). The discussion proceeds with reference to the Figures showing formation of a plurality of memory cells individually comprising programmable material that is elevationally outward of a selector device. Alternately as examples, this elevational relationship can be reversed, an orientation other than elevational used (e.g., lateral and/or diagonal), or no selector device may be within the individual memory cells. In this document, “elevational”, “upper”, “lower”, “top”, and “bottom” are with reference to the vertical direction. “Horizontal” refers to a general direction along a primary surface relative to which the substrate is processed during fabrication, and vertical is a direction generally orthogonal thereto. Further, “vertical” and “horizontal” as used herein are generally perpendicular directions relative one another and independent of orientation of the substrate in three-dimensional space.

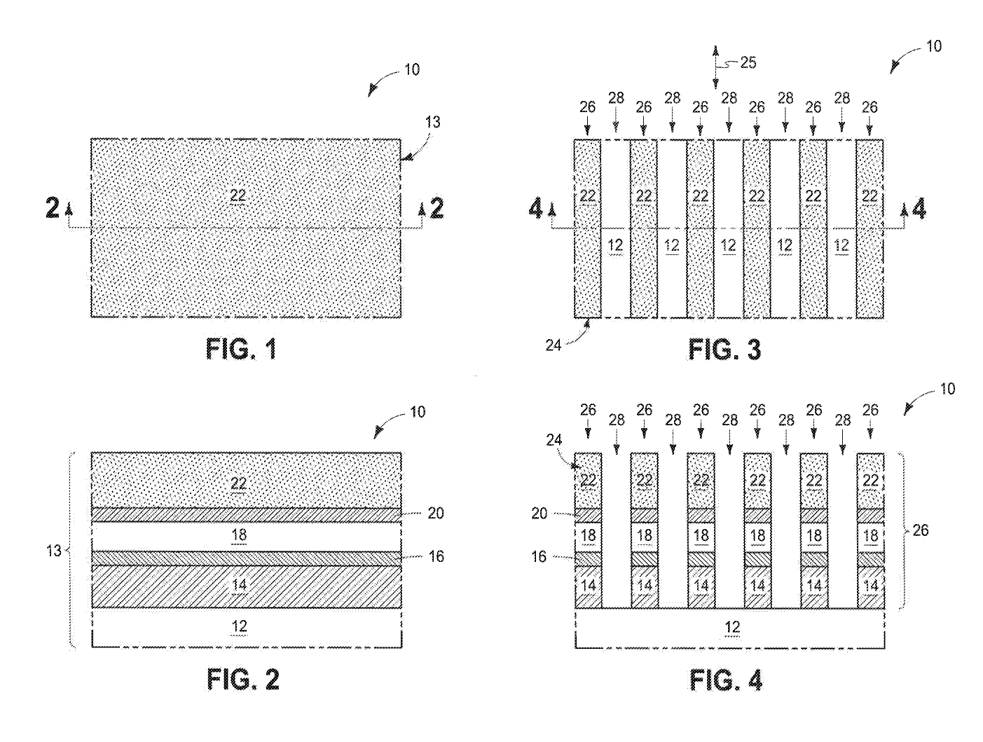

Example embodiments of a method associated with forming a memory cell in accordance with the invention are described with reference to FIGS. 1-26. Referring to FIGS. 1 and 2, a substrate fragment 10 includes a material stack 13 comprising a base or substrate 12 showing various materials having been formed there-over. Materials may be aside, elevationally inward, or elevationally outward of the FIG. 1—depicted materials. For example, other partially or wholly fabricated components of integrated circuitry may be provided somewhere about or within fragment 10. Substrate 12 may comprise any one or more of conductive (i.e., electrically herein), semiconductive, or insulative/insulator (i.e., electrically herein) material(s). Regardless, any of the materials and/or structures described herein may be homogenous or non-homogenous, and regardless may be continuous or discontinuous over any material which such overlie. Further, unless otherwise stated, each material may be formed using any suitable or yet-to-be-developed technique, with atomic layer deposition, chemical vapor deposition, physical vapor deposition, epitaxial growth, diffusion doping, and ion implanting being examples.

Example stack 13 is shown as comprising materials 14, 16, 18, and 20 that are elevationally between a sacrificial material 22 and base material 12. Any suitable thicknesses for such materials may be used. Sacrificial material 22 may be any of conductive, semiconductive, and insulative, with some examples being polyimide, carbon, silicon dioxide, silicon nitride, silicon, and/or aluminum nitride. Materials 16, 18, and 20 may ultimately comprise material of components of individual selector devices and, regardless, material 14 may be conductive to be used for formation of access lines or sense lines within an array of memory cells. Example conductive materials include one or more of elemental metal, an alloy of two or more elemental metals, conductive metal compounds, and conductively doped semiconductive material. Materials 16 and 20 may be conductive, and material 18 may comprise selector device material (e.g., a chalcogenide material) of lesser conductivity than materials 16 and 20. Sacrificial material 22 of stack 13 is over lower conductive material which may be considered as any one or more of materials 14, 16, and 20 where one or more of such are conductive. In some embodiments, stack 13 comprises an intermediate (i.e., in position) conductive material (e.g., material 16 or material 20) that is elevationally between a lower conductive material (e.g., material 14) and sacrificial material 22. In one embodiment, stack 13 comprises a material of lesser conductivity (e.g., material 18) than the intermediate conductive material (e.g., material 20) and which is elevationally between the lower conductive material (e.g., material 14) and the intermediate conductive material (e.g., material 20). In one embodiment, stack 13 may be considered as comprising a pair of elevationally-spaced conductive materials (e.g., materials 16 and 20) having material of lesser conductivity (e.g., material 18) there-between, with such pair being elevationally between the lower conductive material (e.g., material 14) and sacrificial material 22.

Conductive materials 14, 16, and 20 may be of the same composition or of different compositions relative one another. As used herein, “different composition” only requires those portions of two stated materials that may be directly against one another to be chemically and/or physically different, for example if such materials are not homogenous. If the two stated materials are not directly against one another, “different composition” only requires that those portions of the two stated materials that are closest to one another be chemically and/or physically different if such materials are not homogenous. In this document, a material or structure is “directly against” another when there is at least some physical touching contact of the stated materials or structures relative one another. In contrast, “over”, “on”, and “against” not preceded by “directly” encompass “directly against” as well as construction where intervening material(s) or structure(s) result(s) in no physical touching contact of the stated materials or structures relative one another.

Referring to FIGS. 3 and 4, sacrificial material 22 has been subjected to a first patterning in a first direction 25 to form a sacrificial line 24. Multiple same-configuration sacrificial lines are shown, with the discussion in part proceeding with respect to a single sacrificial line 24. When multiple lines are formed, such need not be of the same configuration or oriented parallel relative one another. In the context of fabrication of an array of memory cells, FIGS. 3 and 4 depict an example first patterning step wherein sacrificial material 22 has been patterned to form a series of line stacks 26 that are individually separated by first trenches 28. Line stacks 26 are shown as being straight-linear. Alternately as examples, curvilinear or configurations having combinations of straight and curved segments may be used. Further, reference to “direction” (i.e., where preceded by “first” or “second”) is a generally straight-linear direction although the individual structures patterned in the stated first or second direction may be other than straight, such as curvilinear, etc. Example patterning techniques include etching. For example, photolithographic patterning and etch may be used whereby masking lines (not shown) having individual longitudinal line contours corresponding to those of line stacks 26 as shown in FIG. 3 are formed atop material 22 and used as a mask while etching into material 22 (e.g., with or without hard-masking and/or antireflective materials). Those mask lines may be laterally trimmed prior to etching of material there-below and/or pitch multiplication techniques may be used. Regardless, such patterning may be partially into or wholly through one or more of materials 14, 16, 18, 20, and 22. Ideally, the patterning is at least completely through sacrificial material 22. FIGS. 3 and 4 additionally show the first patterning as having been conducted completely through materials 20, 18, 16, and 14, for example to form conductive material 14 to comprise individual access lines of the memory array being formed.

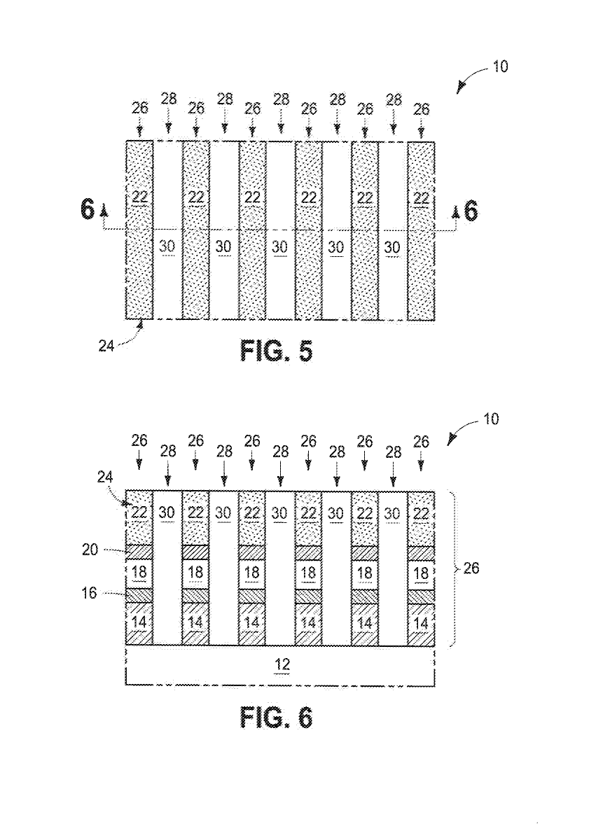

Referring to FIGS. 5 and 6, dielectric material 30 (e.g., silicon dioxide and/or silicon nitride) has been deposited to fill trenches 28, followed by planarization back at least to the elevationally outermost surfaces of sacrificial material 22. Such is but one example of forming a line of dielectric material 30 within individual first trenches 28. Alternate techniques may of course be used.

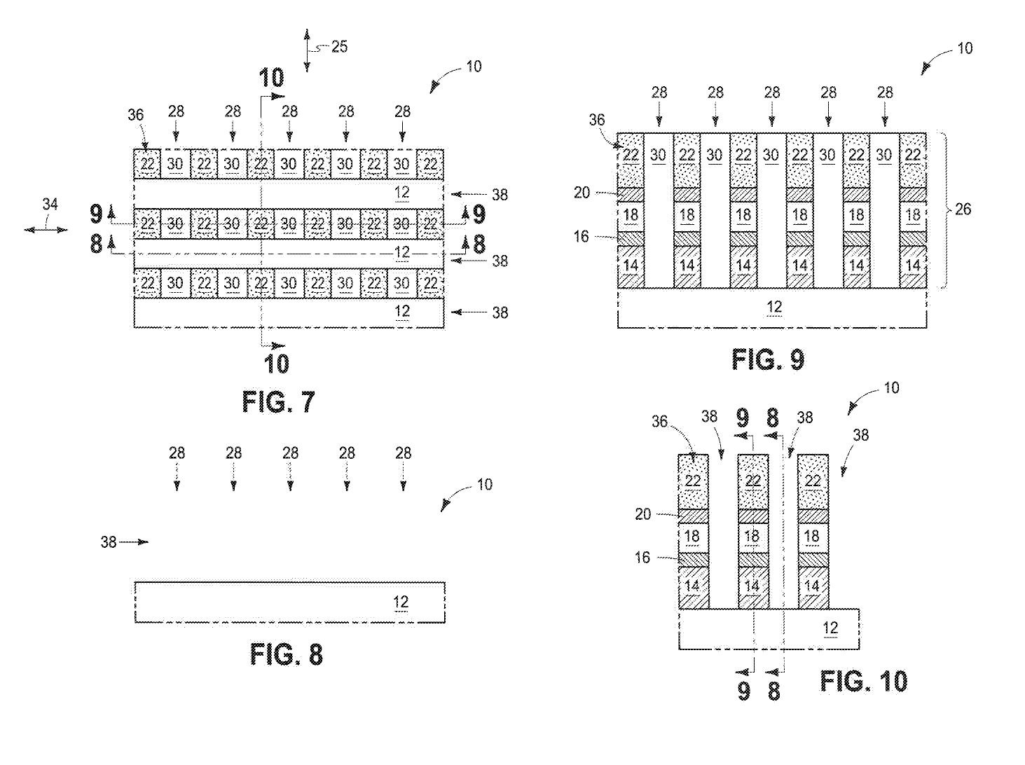

Referring to FIGS. 7-10, after the first patterning, second patterning has been conducted of sacrificial material 22 of sacrificial line 24 (FIGS. 3-6) in a second direction 34 that crosses first direction 25 to form a sacrificial elevationally-extending projection 36 from sacrificial line 24. Reference herein to first and second patternings are only temporally relative one another. Accordingly, additional patterning of the same or other materials may occur before the first patterning, between the first and second patternings, and/or after the second patterning. In fabrication of an array of memory cells and as shown, the second patterning step of FIGS. 7-10 has been conducted after forming lines of dielectric material 30, with sacrificial material 22 and dielectric material 30 having been patterned to form a plurality of spaced sacrificial elevationally-extending projections 36 from sacrificial lines 24 (FIGS. 3-6). Second trenches 38 cross through first trenches 28. Like the first patterning, any suitable existing or yet-to-be developed patterning techniques may be used, with photolithographic patterning and etch (with or without pitch multiplication) being examples. Regardless and as described above with respect to the first patterning, the second patterning may be partially into or elevationally completely through sacrificial material 22 and any of materials 20, 18, 16, and 14. Ideally, the second patterning is at least completely elevationally through sacrificial material 22.

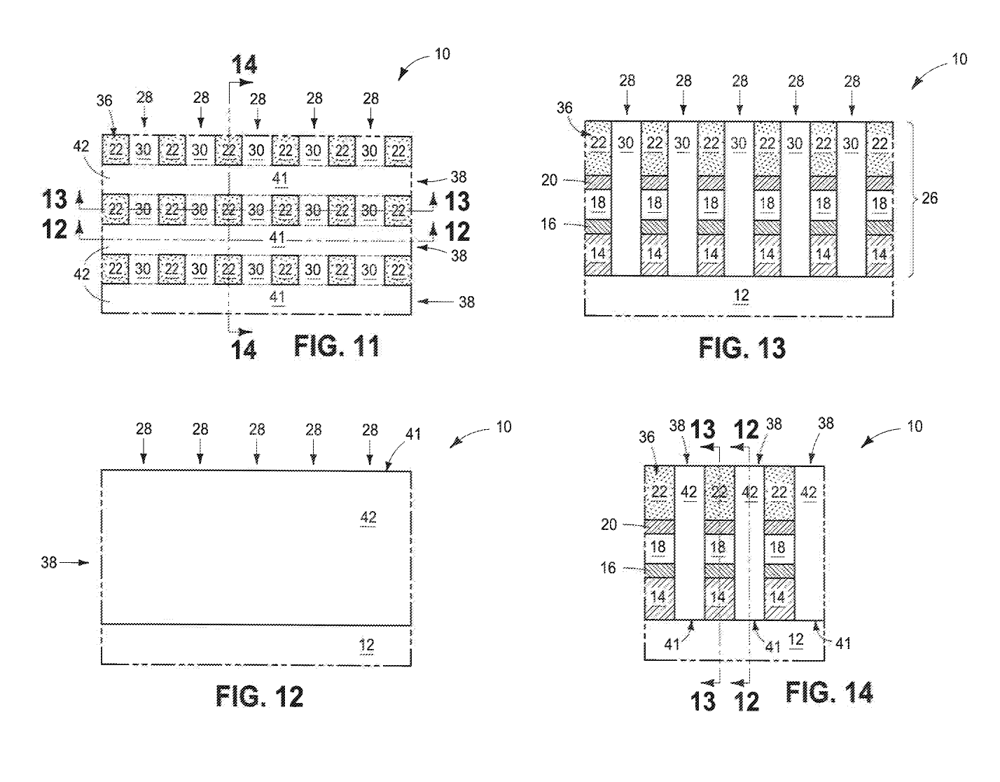

Referring to FIGS. 11-14, a line 41 of dielectric material 42 has been formed within individual second trenches 38. Dielectric material 42 may be of the same composition or of different composition from that of dielectric material 30, and may be formed in the same or different manner(s) as dielectric material 30.

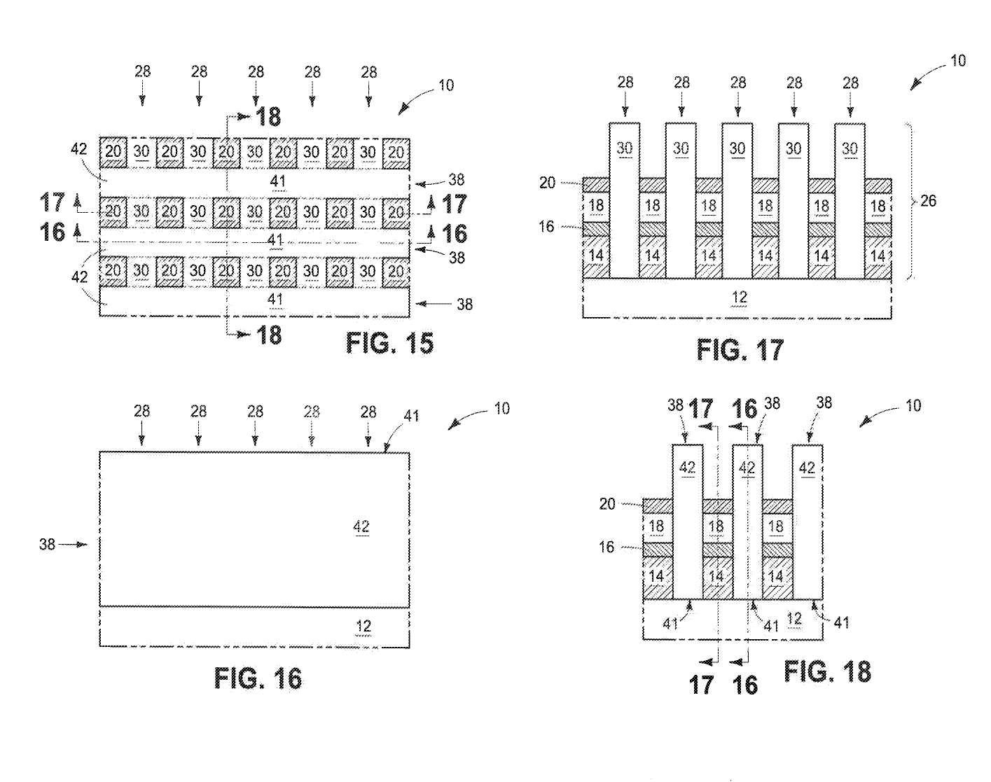

Referring to FIGS. 15-18, sacrificial projections 36 (not shown) of sacrificial material 22 (not shown) have been removed, leaving void spaces. Example techniques for doing so include selective wet or dry etching (e.g., conducted selectively relative to preclude or minimize removal of materials other than sacrificial material 22 that are exposed during such act of etching).

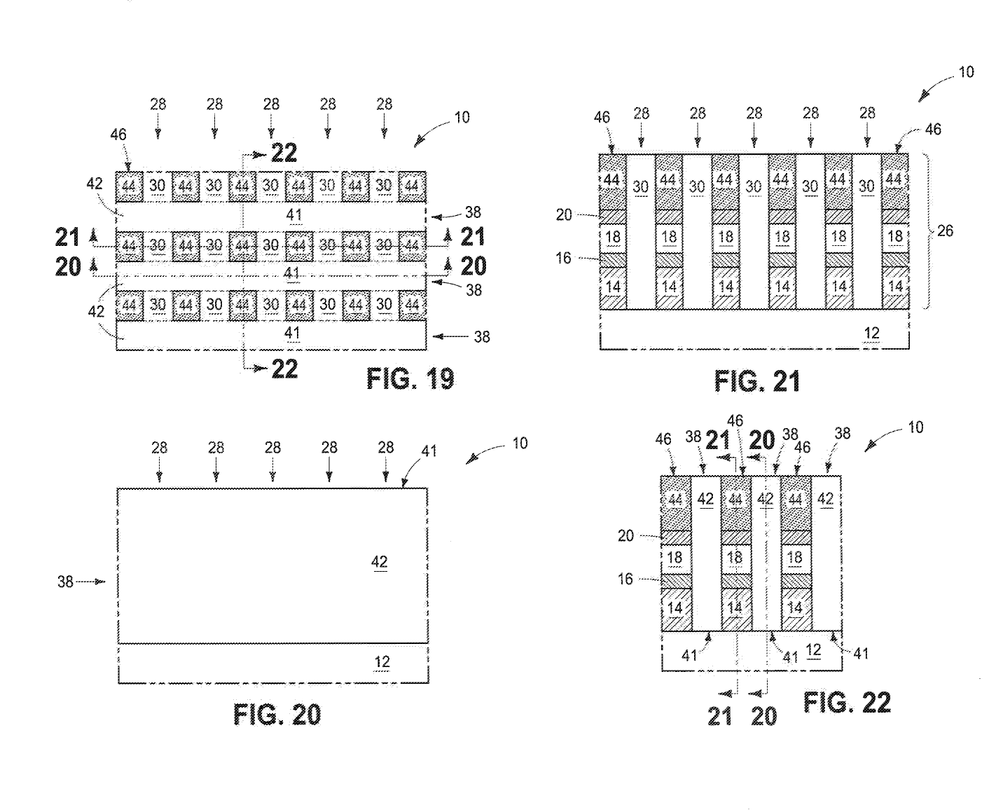

Referring to FIGS. 19-22, and in one embodiment, sacrificial projection 36 of FIGS. 11-14 (not shown in FIGS. 19-22) has been replaced with phase change material 44 to form an elevationally-extending projection 46 comprising phase change material 44. As shown in FIGS. 19-22 in the fabrication of an array of memory cells, such forms a plurality of such spaced elevationally-extending projections 46. An example technique for doing so includes deposition of phase change material 44 to overfill the void-space(s) (FIGS. 15, 17, and 18) left by removal of projection(s) 36, followed by planarization back at least to the elevationally outermost surfaces of dielectric materials 30 and 42. In one embodiment, phase change material 44 comprises chalcogenide material. In one embodiment, dielectric material 30 and dielectric material 42 are directly against phase change material 44, and in one embodiment are of the same composition.

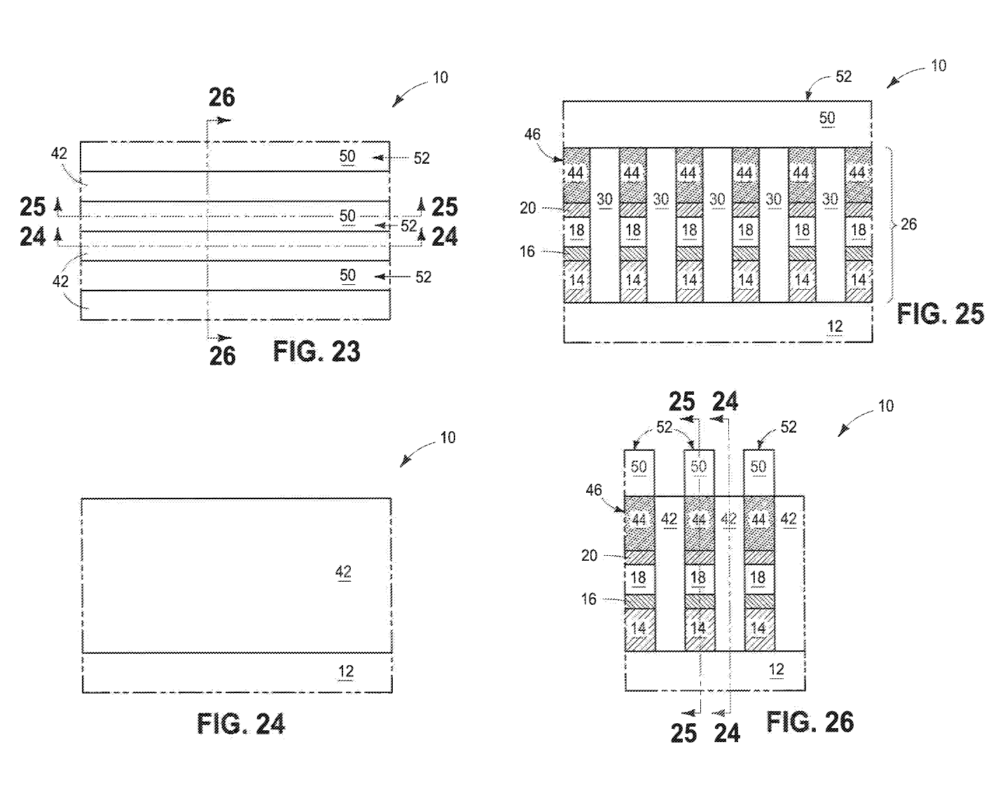

Spaced elevationally-extending projections 46 are incorporated into one of the programmable material or a selector device component of individual memory cells being formed. In one embodiment, the phase change material projections are incorporated into the programmable material of individual memory cells, and regardless of whether such memory cells individually comprise any selector device component. In one embodiment, the memory cells individually comprise a selector device component and the phase change material projections are individually incorporated into the selector device component of the individual memory cells. For example, referring to FIGS. 23-26, conductive material 50 has been deposited and patterned to form conductive lines 52, for example to comprise bit or select lines of the memory cells for an array of memory cells. Such may be formed by any suitable patterning technique(s), for example any of those described above. In producing the structure of FIGS. 23-26 as well as that of FIGS. 7-10, the same mask may be used for each of such masking steps (where masking steps with masks are used).

In one embodiment, a method associated with forming memory cells that comprise programmable material comprises etching sacrificial material (e.g., material 22) to form spaced sacrificial masses (e.g., projections 36) in two separate and time-spaced acts of etching of the sacrificial material. Each of the two acts of etching uses masking lines (e.g., referred to above) outward of the sacrificial material that are different from and angle relative to the masking lines of the other of said two acts of etching. The sacrificial masses are replaced with the programmable material (e.g., material 44) to form spaced masses (e.g., projections 46) of the programmable material. Individual of the spaced programmable material masses are incorporated into programmable material of individual of the memory cells being formed. Any other attribute(s) or aspect(s) as described above and/or shown in the Figures may be used.

In one embodiment, a method associated with forming memory cells that comprise selector device material comprises etching sacrificial material (e.g., material 22) to form spaced sacrificial masses (e.g., projections 36) in two separate and time-spaced acts of etching of the sacrificial material. Each of the two acts of etching uses masking lines (e.g., as referred to above) outward of the sacrificial material that are different from and angle relative to the masking lines of the other of said two acts of etching. The sacrificial masses are replaced with the selector device material (e.g., material 44) to form spaced masses (e.g., projections 46) of the selector device material. Individual of the spaced selector device material masses are incorporated into selector device material of individual of the memory cells being formed. In one embodiment, the selector device comprises a conductive electrode, and the selector device material is of lesser conductivity than the conductive electrode. In one embodiment, the memory cells comprise programmable material and that is formed prior to replacing the sacrificial masses. In one embodiment, the memory cells comprise programmable material and that is formed after replacing the sacrificial masses. Any other attribute(s) or aspect(s) as described above and/or shown in the Figures may be used.

Some of the above-described processing includes separate first and second patternings using different masks. However, such is not required in some embodiments. In one embodiment, a method associated with forming a memory cell that comprises programmable material includes forming a stack comprising sacrificial material over lower conductive material. That sacrificial material is patterned to form a sacrificial elevationally-extending projection (i.e., regardless of whether conducted in one, two, or more patterning steps). The sacrificial projection is replaced with phase change material to form an elevationally-extending projection comprising the phase change material. The phase change material projection is incorporated into one of the programmable material or a selector device component of the memory cell being formed.

The methods described above in connection with the Figures are but example embodiments of patterning the sacrificial material using multiple patterning, masking, and/or etching steps. As an alternate embodiment, such might be conducted using a single masking step. For example, a single masking step and then a single etching step might be conducted to directly form sacrificial elevationally-extending projections 36 of FIGS. 7-10 from FIGS. 1 and 2. This may be followed by a single deposition of dielectric material 42 directly against sidewalls of sacrificial elevationally-extending projections 36 (i.e., after the single etching step). Hard-masking may be used, as well as in the above-described embodiments. Any masking step herein may include double exposure (e.g., using two perpendicular linear masks) and/or pitch multiplication to define sacrificial elevationally-extending projections 36. However, in one embodiment, the patterning of the sacrificial material is conducted using only a single masking step and only a single etching of the sacrificial material.

As ever smaller and denser arrays of memory cells are fabricated, the individual memory cells become both smaller and closer together. Heretofore, part of the dielectric material that was used to separate individual memory cells within the memory array may include dielectric liners deposited against sidewalls of the phase change material of the memory cells, followed by deposition of different composition dielectric material from that of the liner materials. Liners are commonly used to protect the phase change material from contamination during subsequent acts of etching, and are not expected to be practical as minimum spacing between immediately adjacent memory cells is 20 nm or less.

An embodiment of the invention includes an array of memory cells independent of method of manufacture. Such array includes a plurality of laterally-spaced memory cells individually comprising a stack of materials comprising phase change material. The phase change material comprises at least one of programmable material or a selector device component of the individual memory cell. Dielectric material spans laterally between immediately adjacent of the individual memory cells. Such dielectric material is directly against the phase change material of the immediately adjacent individual memory cells and is homogenous there-between. In one embodiment, minimum spacing between immediately adjacent surfaces of the phase change material of different memorial cells is no greater than 20 nm. As an example, FIGS. 23-26 represent an array of memory cells, with individual of the memory cells comprising individual stacks of materials 16, 18, 20, 44 between conductive lines 14 and 50, and which may include conductive material of lines 14 and 50. Dielectric materials 30 and 42 may be of the same composition (i.e., homogenous) and directly against sidewalls of phase change material 44 (i.e., no different composition liners being directly against and part of same-composition dielectric materials 30 and 42).

An Appendix is provided herewith and constitutes part of this document as if provided textually herein before the claims in this document. The Appendix is U.S. patent application Ser. No. 14/228,104, filed on Mar. 27, 2014, (now U.S. Patent Publication No. ______ published on) ______). Accordingly, such is fully herein incorporated as if part of this document, and with any conflict, if any, between the two documents to be resolved in favor of this document as if the Appendix was not included herewith. The Appendix does not disclose the acts of separate first and second patternings of the sacrificial material that is ultimately replaced whereas the non-Appendix part of this document does.

### CONCLUSION

In some embodiments, a method associated with forming a memory cell that comprises programmable material comprises forming a stack comprising sacrificial material over lower conductive material. The sacrificial material is first patterned in a first direction to form a sacrificial line. After the first patterning, second patterning is conducted of the sacrificial material of the sacrificial line in a second direction that crosses the first direction to form a sacrificial elevationally-extending projection from the sacrificial line. The sacrificial projection is replaced with phase change material to form an elevationally-extending projection comprising the phase change material. The phase change material projection is incorporated into one of the programmable material or a selector device component of the memory cell being formed.

In some embodiments, a method associated with forming memory cells that comprise programmable material comprises forming a stack comprising sacrificial material over lower conductive material. In a first patterning step, the sacrificial material is patterned to form a series of line stacks. The first patterning step forms individual of the line stacks to be separated by first trenches and to comprise a line of the sacrificial material. The line of sacrificial material is over the lower conductive material. A line of dielectric material is formed within individual of the first trenches. In a second patterning step after forming the lines of dielectric material, the sacrificial material and the dielectric material are patterned to form spaced sacrificial elevationally-extending projections from the sacrificial material of the lines of sacrificial material. The second patterning step forms second trenches that cross through the first trenches. A line of dielectric material is formed within individual of the second trenches. The sacrificial projections are replaced with phase change material to form spaced elevationally-extending projections comprising the phase change material. The spaced phase change material projections are incorporated one of the programmable material or a selector device component of individual of the memory cells being formed.

In some embodiments, a method associated with forming memory cells that comprise programmable material comprises etching sacrificial material to form spaced sacrificial masses in two separate and time-spaced acts of etching of the sacrificial material. Each of the two acts of etching uses masking lines outward of the sacrificial material that are different from and angle relative to the masking lines of the other of said two acts of etching. The sacrificial masses are replaced with the programmable material to form spaced masses of the programmable material. Individual of the spaced programmable material masses are incorporated into programmable material of individual of the memory cells being formed.

In some embodiments, a method associated with forming memory cells that comprise selector device material comprises etching sacrificial material to form spaced sacrificial masses in two separate and time-spaced acts of etching of the sacrificial material. Each of the two acts of etching uses masking lines outward of the sacrificial material that are different from and angle relative to the masking lines of the other of said two acts of etching. The sacrificial masses are replaced with the selector device material to form spaced masses of the selector device material. Individual of the spaced selector device material masses are incorporated into selector device material of individual of the memory cells being formed.

In some embodiments, a method associated with forming a memory cell that comprises programmable material comprises forming a stack comprising sacrificial material over lower conductive material. The sacrificial material is patterned to form a sacrificial elevationally-extending projection. The sacrificial projection is replaced with phase change material to form an elevationally-extending projection comprising the phase change material. The phase change material projection is incorporated into one of the programmable material or a selector device component of the memory cell being formed.

In some embodiments, an array of memory cells comprises a plurality of laterally-spaced memory cells individually comprising a stack of materials comprising phase change material. The phase change material comprises at least one of programmable material or a selector device component of the individual memory cell. Dielectric material spans laterally between immediately adjacent of the individual memory cells. Such dielectric material is directly against the phase change material of the immediately adjacent individual memory cells and is homogenous there-between.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method associated with forming a memory cell that comprises programmable material, comprising:
forming a stack comprising sacrificial material over lower conductive material;
first patterning the sacrificial material in a first direction to form a sacrificial line;
after the first patterning, second patterning the sacrificial material of the sacrificial line in a second direction that crosses the first direction to form a sacrificial elevationally-extending projection from the sacrificial line;
replacing the sacrificial projection with phase change material to form an elevationally-extending projection comprising the phase change material; and
incorporating the phase change material projection into one of the programmable material or a selector device component of the memory cell being formed.

2. The method of claim 1 wherein the phase change material comprises chalcogenide material.

3. The method of claim 1 wherein the memory cell comprises a selector device component, and the phase change material projection is incorporated into the selector device component.

4. The method of claim 1 wherein the phase change material projection is incorporated into the programmable material of the memory cell.

5. The method of claim 4 wherein the memory cell comprises a selector device component.

6. The method of claim 1 wherein the first patterning and/or the second patterning comprises etching into the sacrificial material.

7. The method of claim 6 wherein the etching is conducted completely elevationally through the sacrificial material.

8. The method of claim 1 wherein the first patterning and the second patterning each comprises etching that is conducted completely elevationally through the sacrificial material.

9. The method of claim 1 comprising forming the stack to comprise an intermediate conductive material elevationally between the lower conductive material and the sacrificial material.

10. The method of claim 9 wherein the first patterning is elevationally completely through the sacrificial material.

11. The method of claim 10 wherein the first patterning is elevationally into the intermediate conductive material.

12. The method of claim 11 wherein the first patterning is elevationally completely through the intermediate conductive material.

13. The method of claim 12 wherein the second patterning is elevationally completely through the sacrificial material and the intermediate conductive material.

14. The method of claim 9 comprising forming the stack to comprise a material of lesser conductivity than the intermediate conductive material elevationally between the lower conductive material and the intermediate conductive material.

15. The method of claim 1 comprising forming the stack to comprise a pair of elevationally-spaced conductive materials having material of lesser conductivity elevationally there-between, the pair being elevationally between the lower conductive material and the sacrificial material.

16. The method of claim 15 wherein the first patterning is elevationally completely through the sacrificial material.

17. The method of claim 16 wherein the first patterning is elevationally completely through the pair of elevationally-spaced conductive materials and material of lesser conductivity elevationally there-between.

18. The method of claim 17 wherein the second patterning is elevationally completely through the pair of elevationally-spaced conductive materials and material of lesser conductivity elevationally there-between.

19. A method associated with forming memory cells that comprise programmable material, comprising:
forming a stack comprising sacrificial material over lower conductive material;
in a first patterning step, patterning the sacrificial material to form a series of line stacks, the first patterning step forming individual of the line stacks to be separated by first trenches and to comprise a line of the sacrificial material, the line of sacrificial material being over the lower conductive material;
forming a line of dielectric material within individual of the first trenches;
in a second patterning step after forming the lines of dielectric material, patterning the sacrificial material and the dielectric material to form spaced sacrificial elevationally-extending projections from the sacrificial material of the lines of sacrificial material, the second patterning step forming second trenches that cross through the first trenches;
forming a line of dielectric material within individual of the second trenches;
replacing the sacrificial projections with phase change material to form spaced elevationally-extending projections comprising the phase change material; and
incorporating the spaced phase change material projections into one of the programmable material or a selector device component of individual of the memory cells being formed.

20. The method of claim 19 wherein, during the first patterning step, the lower conductive material is patterned to form the individual line stacks to comprise a lower line of the lower conductive material beneath the line of sacrificial material.

21. A method associated with forming memory cells that comprise programmable material, comprising:
etching sacrificial material to form spaced sacrificial masses in two separate and time-spaced acts of etching of the sacrificial material, each of the two acts of etching using masking lines outward of the sacrificial material that are different from and angle relative to the masking lines of the other of said two acts of etching;
replacing the sacrificial masses with the programmable material to form spaced masses of the programmable material; and
incorporating individual of the spaced programmable material masses into programmable material of individual of the memory cells being formed.

22. A method associated with forming memory cells that comprise selector device material, comprising:
etching sacrificial material to form spaced sacrificial masses in two separate and time-spaced acts of etching of the sacrificial material, each of the two acts of etching using masking lines outward of the sacrificial material that are different from and angle relative to the masking lines of the other of said two acts of etching;
replacing the sacrificial masses with the selector device material to form spaced masses of the selector device material; and
incorporating individual of the spaced selector device material masses into selector device material of individual of the memory cells being formed.

23. The method of claim 22 wherein the selector device comprises a conductive electrode, the selector device material being of lesser conductivity than the conductive electrode.

24. The method of claim 22 wherein the memory cells comprise programmable material, and comprising forming the programmable material of the memory cells prior to replacing the sacrificial masses.

25. A method associated with forming a memory cell that comprises programmable material, comprising:
forming a stack comprising sacrificial material over lower conductive material;
patterning the sacrificial material to form a sacrificial elevationally-extending projection;
replacing the sacrificial projection with phase change material to form an elevationally-extending projection comprising the phase change material; and
incorporating the phase change material projection into one of the programmable material or a selector device component of the memory cell being formed.

26. The method of claim 25 wherein the patterning of the sacrificial material is conducted using only a single masking step and only a single etching step of the sacrificial material.

27. The method of claim 26 comprising conducting a single deposition of dielectric material directly against sidewalls of the sacrificial elevationally-extending projection after the single etching step.

28. An array of memory cells, comprising:
a plurality of laterally-spaced memory cells individually comprising a stack of materials comprising phase change material, the phase change material comprising at least one of programmable material or a selector device component of the individual memory cell; and
dielectric material spanning laterally between immediately adjacent of the individual memory cells, said dielectric material being directly against the phase change material of the immediately adjacent individual memory cells and being homogenous there-between.

29. The method of claim 28 wherein minimum spacing between immediately adjacent surfaces of the phase change material of different memory cells is no greater than 20 nanometers.
